(19) United States
(12) Patent Application Publication
(10) Pub. No.: US 2020/0388508 A1
(43) Pub. Date: Dec. 10, 2020

(54) REPASSIVATION APPLICATION FOR WAFER-LEVEL CHIP-SCALE PACKAGE

(71) Applicant: Texas Instruments Incorporated, Dallas, TX (US)

(72) Inventors: Makoto Shibuya, Beppu City (JP); Daiki Komatsu, Beppu City (JP); Yi Yan, Milpitas, CA (US); Hau Nguyen, San Jose, CA (US); Luu Thanh Nguyen, San Jose, CA (US)

(21) Appl. No.: 16/431,613

(22) Filed: Jun. 4, 2019

(51) Int. Cl. H01L 21/56; H01L 23/00; H01L 21/78; H01L 21/02

(52) U.S. Cl. CPC H01L 21/56; H01L 24/94; B05D 3/067; H01L 21/02288; H01L 21/02348; H01L 21/78

(57) ABSTRACT

In described examples, a method of printing repassivation onto a substrate includes depositing an ink comprising particles of a repassivation material onto specified locations on a surface of the substrate using an inkjet printer, and curing the repassivation material. The ink is deposited so that specified portions of the substrate surface are not covered by the ink

### BACKGROUND

This application relates generally to electronic circuitry, and more particularly to methods for applying repassivation material to die surfaces to protect exposed conductive lines and vias.

FIG. 1A shows an example of a prior art integrated circuit 100 (die) for use in a wafer-level chip-scale package (WLCSP). WLCSP is a packaging technology in which the package size equals or slightly exceeds the die size, and is typically used to enable the die to be directly mounted on and electrically connected to a printed circuit board (PCB) or other system-level mount (a platform with circuits connecting the WLCSP to other integrated circuits or other electrically functional structures). For example, for a package to be considered a chip-scale package, the Association Connecting Electronics Industries (IPC) J-STD-012 standard, Implementation of Flip Chip and Chip Scale Technology, requires the package to have an area no greater than 1.2 times that of the die, and to be a single-die package with a surface directly mountable on the system-level mount.

As shown in FIG. 1A, the die 100 includes an exposed die surface 102, on which are printed or plated multiple conductive traces 104, and on to which extend multiple conductive pillars 106. The die surface 102 is protected by glassivated passivation which can include, for example, silicon nitride (SiN) or silicon oxynitride (SiON). The conductive traces 104 are connected to the conductive pillars 106 which extend into, and connect to circuits (not shown) within, the internal body of the die 100. The conductive traces 104 can be used for, for example, signal routing or thermal connection for heat dissipation. Both the conductive traces 104, and surfaces comprising ends of respective ones of the conductive pillars 106, are exposed on the die surface 102. Exposed surfaces of the conductive pillars 106 are shown in FIG. 1A. The conductive pillars 106 can extend up to, for example, 18 μm above the die surface 102. The exposed surfaces of the conductive pillars 106 are located on what is typically referred to as an “active side” of the die 100. The exposed conductive pillars 106 on the active side of the die 100 are used to connect circuits within the die 100 to circuits on a PCB or other system-level mount.

Conductive traces 104 and conductive pillars 106 are typically made of copper. As fabricated, the conductive traces 104 are exposed on the die surface 102. Accordingly, the conductive traces 104 on the die surface 102 are not protected by an encapsulant or a molding compound. When exposed to a moist environment and under bias, copper conductive traces 104 can experience corrosion and whisker growth, potentially resulting in shorting among adjacent conductive traces 104. Consequently, exposed surfaces 102 of dies 100 for use in WLCSPs are generally coated with a repassivation material, which is a non-reactive material (such as a polymer) which protects the die surface 102 and conductive traces 104 against whiskering and other reactive environmental hazards (also referred to herein as reactive environmental factors). Exposed surfaces of conductive pillars 106 are not coated with repassivation material to enable the conductive pillars 106 to be electrically connected to a system-level mount (for example, using solder balls) such as a PCB.

FIG. 1B shows an example prior art view 108 of a die 100 for use in a WLCSP after a polymeric repassivation 110 has been applied to the surface 102 (not visible) of the die 100. Repassivation 110 is typically applied using spin coating of a photosensitive material that can be patterned as a repassivation material. The photosensitive material can be from a variety of chemical families such as epoxies, BMI (Bismaleimide), silicones, polyimides, or combinations thereof. Spin coating results in the photosensitive material covering the entirety of the die surface 102, including up to the top surface of the conductive pillars 106. Spin coating also results in photosensitive material being spun off the wafer, typically wasting 80% or more of the photosensitive material. The photosensitive material on the wafer is then polymerized by optical exposure using masks to prevent exposure of portions of the photosensitive material covering the conductive pillars 106 and covering portions of the photosensitive material between different dies. (Accordingly, between different electrically disjoint integrated circuits fabricated in the substrate.) Excess photosensitive material can be washed away or otherwise removed, leaving patterned repassivation 110. Patterned repassivation 110 leaves the conductive pillars 106 and scribe 112 (a portion of the substrate which is safe to cut to separate dies 100) exposed.

### SUMMARY

In described examples, a method of printing repassivation onto a substrate includes depositing an ink comprising particles of a repassivation material onto specified locations on a surface of the substrate using an inkjet printer, and curing the repassivation material. The ink is deposited so that specified portions of the substrate surface are not covered by the ink

### BRIEF DESCRIPTION OF THE DRAWINGS

FIG. 1A shows an example of a prior art integrated circuit (die) for use in a wafer-level chip-scale package (WLCSP).

FIG. 1B shows an example prior art view of a die for use in a WLCSP after a polymeric repassivation has been applied to the surface of the die.

FIG. 2 shows a side view of an example of an inkjet printer used to deposit material on a substrate surface.

FIG. 3A shows an example inkjet printing pattern for selectively coating in repassivation material a die surface as shown in FIG. 1A.

FIG. 3B shows an example view of a die for use in a WLCSP after a polymeric repassivation has been selectively applied to the surface of the die.

FIG. 3C shows an example inkjet printing pattern 314 for selectively coating in repassivation material a die for use in a WLCSP to produce the repassivation-coated die surface as shown in FIG. 3B.

FIG. 4 shows an example process for depositing repassivation on a die surface using an inkjet printer.

FIG. 5 shows an example system for depositing repassivation on a die surface using an inkjet printer, cutting a corresponding wafer into separate dies, and electrically connecting the die to a PCB using solder balls.

FIG. 6 shows an example process for making an integrated circuit.

### DETAILED DESCRIPTION

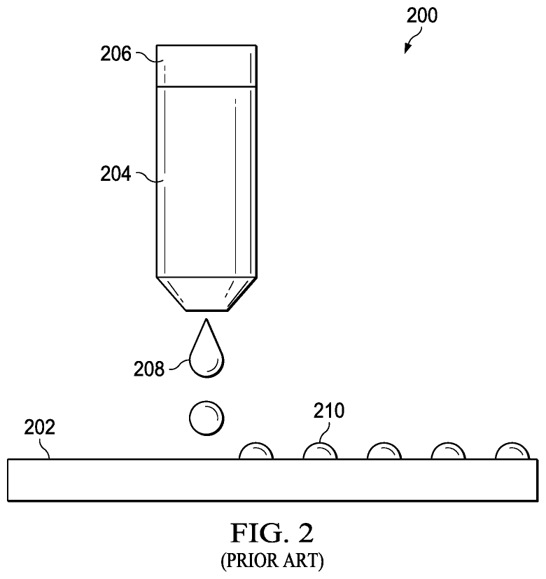

FIG. 2 shows a side view of an example of an inkjet printer 200 used to deposit liquid material on a substrate surface 202. The substrate surface 202 may represent, for example, a surface of a wafer, in which numerous integrated circuits are formed. As shown in FIG. 2, an inkjet printer 200 comprises a nozzle 204 which emits liquid material supplied by a reservoir 206. An actuator (not shown) causes material to be emitted from the nozzle 204 as liquid droplets 208. The droplets 208 impact and are adsorbed by the substrate surface 202, forming liquid beads 210 that are held together by surface tension. The timing of droplets 208 being ejected from the inkjet printer 200 as the inkjet printer 200 moves over the surface 202 determines the resulting pattern formed. Ejection of droplets 208 from the inkjet printer 200 can correspond to droplets 208 being ejected from the nozzle 204, or from another structure between the nozzle 204 and the substrate surface 202, such as a catcher (not shown).

Inkjet printers as used for deposition of semiconductor device-related materials, and as the noun “inkjet printer” is used herein, are not the inkjet printers used in business offices to print legible documents and images. Instead, “inkjet printer” as used herein refers to mechanisms for deposition of volumes of liquids (“inks”) onto a surface on picoliter or femtoliter scales, wherein the so-called “inks” contain semiconductor processing-related nanoparticles and/or precursors in suspension. For example, a nozzle between 35 and 60 μm in diameter, producing a droplet between 4 and 14 pL (picoliters) in volume, can be used. (Other nozzle and droplet sizes can also be used.) The ink can then be dried, and the materials previously suspended in the ink annealed, to form permanent structures on the surface onto which the ink was deposited. The term “inkjet printer” is used because a business office inkjet printer, and an inkjet printer as described herein, have some analogous functions.

Inkjet printing as described herein is a non-contact, additive, fabrication and patterning process. Patterned materials are directly deposited in a specified pattern, generally without using masks or stencils. Once an ink is deposited, the ink is dried, and energy is applied to cause the deposited materials to react to form the desired layer. Inkjet printing can be used to pattern repassivation 110 onto a substrate surface 202, by including particles of repassivation material in an ink with appropriate viscosity and other properties. Deposited repassivation material can be “cured”—caused to form a layer of repassivation 110—using UV pinning (ultraviolet light pinning), or thermal energy, or both. For example, reaction energy can be provided by using a fast UV-pinning cure and then “baking” the substrate in an oven.

The inkjet printer 200 preferably uses highly precise positional control (for example, using a dedicated inkjet controller) to enhance the resolution with which repassivation-laden ink is printed on the substrate surface 202. Preferably, the inkjet printer's 200 print resolution is high enough to enable minimization of a portion of a die surface 102 which is printed onto but which does not include conductive traces 104 or other sensitive structures or materials. Print resolution is influenced by multiple factors, including droplet size, droplet frequency, properties of the ink (such as viscosity, surface tension, repassivation particle concentration, and chemical makeup), and precision of positional control.

In fluid dynamics, it is common to work with “kinematic viscosity”, which is the ratio of the dynamic viscosity of a fluid to its density. Dynamic viscosity measures the force needed to overcome internal friction in a fluid. Typical photosensitive repassivation materials have a kinematic viscosity of 4000 to 5000 centistokes. Inkjet printers 200 with resolution in the +/−5 μm range may, for example, require a kinematic viscosity of approximately 20 to 30 centistokes. Inks with other kinematic viscosities can also be used, depending on, for example, the diameter of the nozzle used by the inkjet printer's 200 printhead (not shown), a temperature of the printhead, ambient temperature, printed pattern accuracy of the printer, and print layer thickness.

In some embodiments using a thermally curable repassivation material, a corresponding ink can have a high repassivation solid content, for example a 60% to 70% repassivation solid content by mass. Solvent evaporates during the thermal curing process.

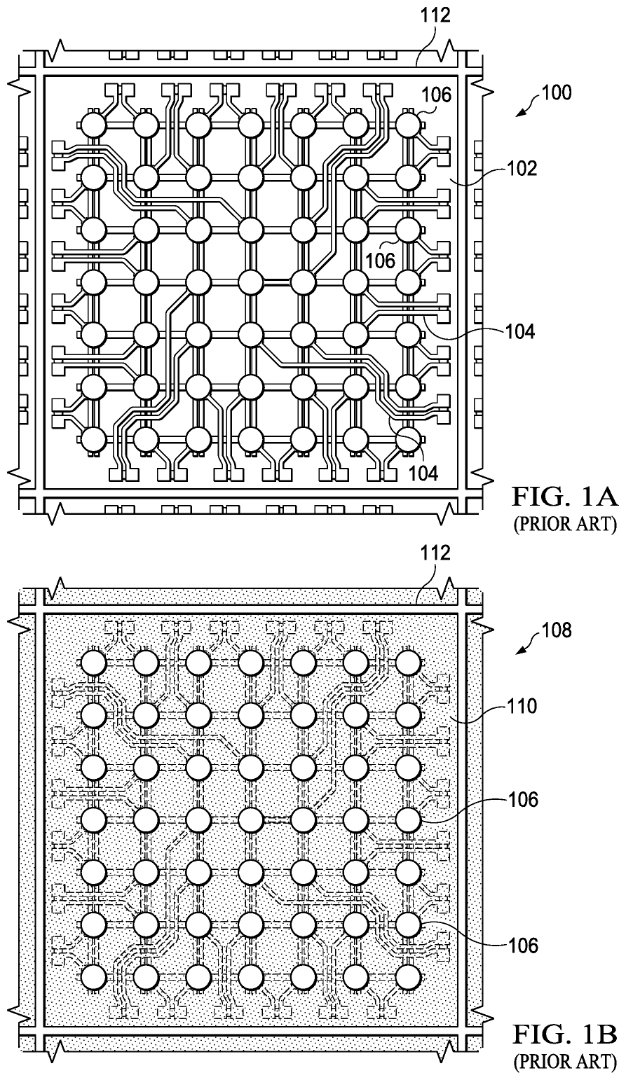

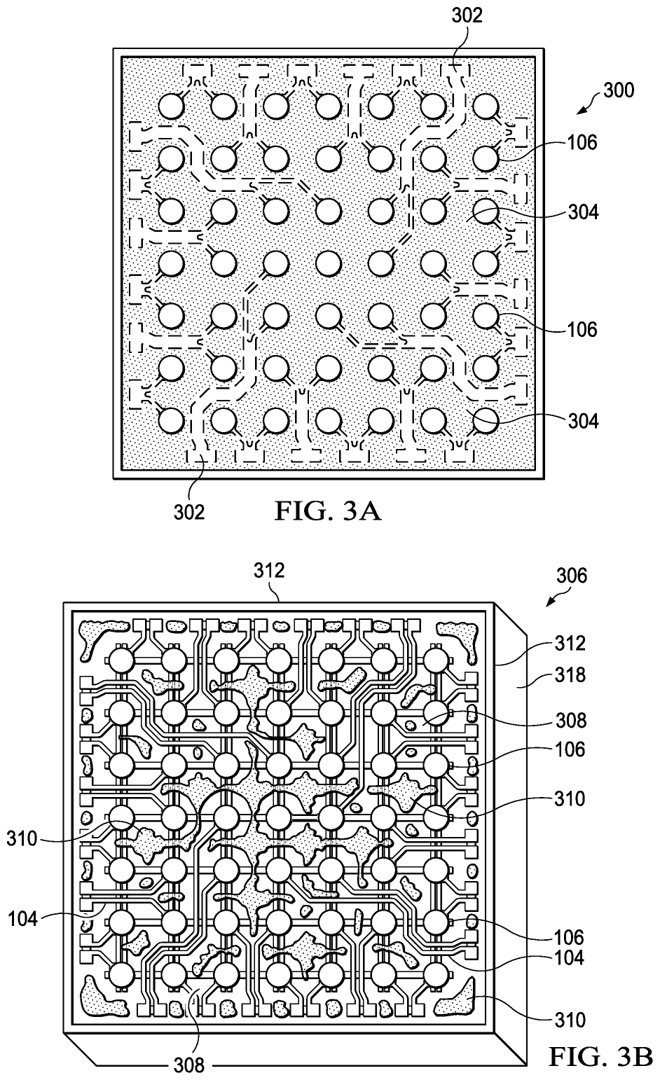

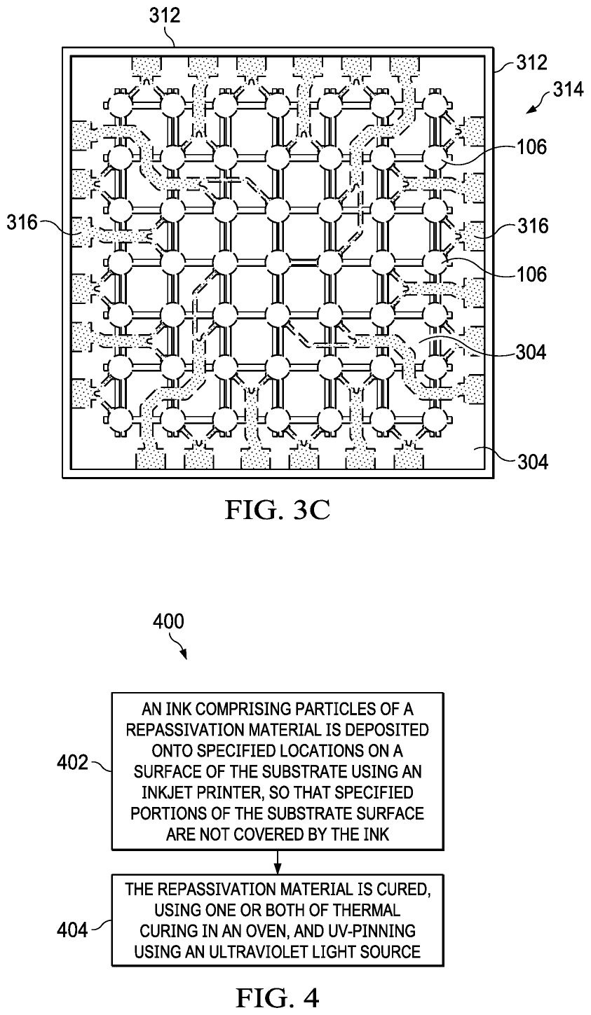

FIG. 3A shows an example inkjet printing pattern 300 for selectively coating in repassivation material a die surface 102 as shown in FIG. 1A. The inkjet printing pattern 300 includes regions to be printed 302 and regions not to be printed 304. Regions to be printed 302 are regions where repassivation material will be deposited by the inkjet printer 200. Regions not to be printed 304 are regions where repassivation material will not be deposited by the inkjet printer 200.

As shown in and described with respect to FIG. 1A, the die surface 102 includes exposed conductive traces 104 and conductive pillars 106. Regions to be printed 302 (deposition of repassivation material) can be limited to environmentally vulnerable components, reducing the amount of wasted repassivation material and corresponding ink, which reduces cost and environmental impact. A selective repassivation material deposition process using an inkjet printer 200 can result in a nearly 100% efficient usage of repassivation material-laden ink (accordingly, little or no wasted ink), as well as increased throughput over blanket deposition processes due to enabling usage of fewer printing passes to deposit repassivation material. These advantages are obtained both over a blanket process using photosensitive repassivation material as described with respect to FIG. 1B, and over a blanket process using an inkjet printer 200. A blanket process using an inkjet printer 200 wastes the ink printed on the conductive pillars 106 and scribe (resulting in, for example, a 95% efficient usage of repassivation material-laden ink), and may require masks for UV exposure.

Environmentally vulnerable components are those which, without a coating of repassivation 110, have an elevated risk of accelerated die 100 performance loss, caused by environmental exposure to reactive materials (such as moisture), to compromise the design specifications (such as lifetime) of the die 100. Vulnerable components include conductive traces 104 and, in some embodiments, other functional components, or regions of exposed SiN or SiON on the die surface 102. The efficacy of limitation by the inkjet printer 200 of deposition of repassivation material to vulnerable components is responsive to the resolution of the inkjet printer 200 used to deposit repassivation material, fabrication tolerances, and properties of the repassivation material (such as repassivation 110 thickness required to provide designed protection). Pattern locations 302 for repassivation material deposition can be selected to cover, for example, conductive traces 104, to not cover conductive pillars 106, and to be limited to portions of the die surface 102 which include vulnerable (or other function-critical) components.

Also, the die 100 can be designed so that less die surface 102 area contains vulnerable components, and die surface 102 area containing vulnerable components has a higher density of vulnerable components. This can help mitigate limitations of inkjet printer 200 resolution, so that if resolution is insufficient to prevent “spillover”—repassivation material printed on portions of the die surface 102 which are adjacent to, but not part of, portions of the die surface 102 (and components thereon) which are intended to be protected by repassivation 110—then total spillover can be reduced, reducing wasted ink.

In some embodiments, the same design layout database used to print trace patterns on a die can be used by an inkjet printer to specify regions to be printed 302 and regions not to be printed 304.

Additional advantages of using an inkjet printing process rather than a spin-on and optical exposure and development process include: reduced man-hours used to apply repassivation, and improved control of wafer warpage due to selective printing over metal areas.

FIG. 3B shows an example view of a die 306 for use in a WLCSP after a polymeric repassivation has been selectively applied to the surface of the die 306. An inkjet printer has been used to selectively print repassivation material onto portions 308 of the die surface, while not printing repassivation material onto other portions 310 of the die surface. Scribe lines 312 have been left uncovered by repassivation material. Conductive pillars 106 extend into the body 318 of the die 306 (beneath the die surface) to electrically connect to one or more integrated circuits fabricated in the body 318 of the die 306. The conductive traces 104 and conductive pillars 106 can also be viewed as portions of the integrated circuits which extend onto the die surface.

FIG. 3C shows an example inkjet printing pattern 314 for selectively coating in repassivation material a die 306 for use in a WLCSP to produce the repassivation-coated die surface as shown in FIG. 3B. The inkjet printing pattern 314 of FIG. 3C shows regions 316 of the die surface designated for deposition of repassivation material. The regions 316 designated for deposition are located so that deposited repassivation material will overlay—and, after curing, protect—conductive traces 104 and regions surrounding the conductive pillars 106.

FIG. 4 shows an example process 400 for depositing repassivation on a die surface using an inkjet printer. As shown in FIG. 4, in step 402, an ink comprising particles of a repassivation material is deposited onto specified locations on a surface of the substrate using an inkjet printer, so that specified portions of the substrate surface are not covered by the ink. In step 404, the repassivation material is cured, using one or both of thermal curing in an oven, and UV-pinning using an ultraviolet light source.

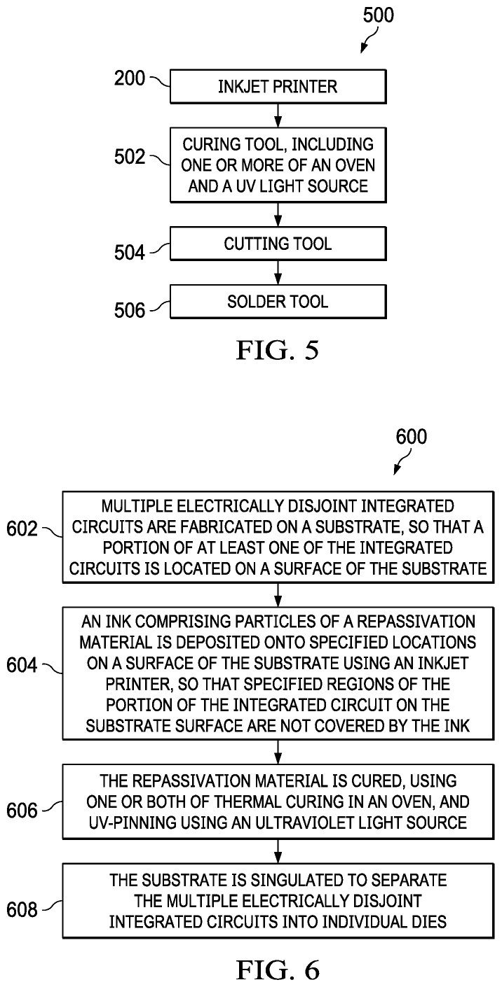

FIG. 5 shows an example system 500 for depositing repassivation on a die surface using an inkjet printer, cutting a corresponding wafer into separate dies, and electrically connecting the die to a PCB using solder balls. The system includes an inkjet printer 200, a curing tool 502 comprising one or both of an oven (for thermal curing) or an ultraviolet light source, a cutting tool 504 for cutting a wafer (or other substrate) into individual dies, and a solder tool 506 for soldering an assembled WLCSP package including a die onto a system-level mount (such as a PCB). The inkjet printer 200 is configured to deposit ink containing repassivation material to selected areas of a wafer. In some embodiments, only wafer areas which require protection from repassivation are designated to receive deposited repassivation material.

FIG. 6 shows an example process 600 for making an integrated circuit. As shown in FIG. 6, in step 602, multiple electrically disjoint integrated circuits are fabricated on a substrate, so that a portion of at least one of the integrated circuits (for example, a portion of each integrated circuit, such as conductive leads and conductive pillars) is located on a surface of the substrate. In step 604, an ink comprising particles of a repassivation material is deposited onto specified locations on the substrate surface using an inkjet printer, so that specified regions of the portion of the integrated circuit on the substrate surface are not covered by the ink. The specified locations include at least part of portion of the integrated circuit located on the substrate surface. In step 606, the repassivation material is cured. In step 608, the substrate is singulated to separate the multiple electrically disjoint integrated circuits into individual dies.

Modifications are possible in the described embodiments, and other embodiments are possible, within the scope of the claims.

In some embodiments, a WLCSP is not fully compliant with IPC standards.

In some embodiments, conductive traces are copper lines.

In some embodiments, conductive pillars are copper pillars.

In some embodiments, various types of drop deposition using inkjet printing can be used to apply repassivation pattern to a substrate surface.

In some embodiments, compatibility with a Mahoh or other laser tool for die cutting (which can perform so-called “stealth laser dicing”) is preserved by the inkjet not printing repassivation material on the scribe. Stealth laser dicing is performed by creating defect regions by scanning a laser beam along the scribe lines, and then expanding a wafer carrier membrane to cause fractures to form from the defects, splitting the dies along the scribe lines. In some embodiments, another type of singulation is used.

In some embodiments, conductive vias are also exposed on the surface of a die, comprise environmentally vulnerable components, and are coated with repassivation using an inkjet printer.

In some embodiments, if the viscosity of the ink is temperature sensitive, the viscosity of an ink which is relatively high viscosity at room temperature can be lowered during jetting (printing) by heating the printhead.

1. A method of printing repassivation onto a substrate, the method comprising:
depositing an ink comprising particles of a repassivation material onto specified locations on a surface of the substrate using an inkjet printer, so that specified portions of the substrate surface are not covered by the ink; and
curing the repassivation material.

2. The method of claim 1, wherein the curing comprises applying heat to the substrate to anneal the repassivation material, or applying ultraviolet (UV) light to the surface of the substrate to effect UV-pinning on the repassivation material.

3. The method of claim 1, wherein the curing comprises applying ultraviolet (UV) light to the surface of the substrate to effect UV-pinning, and applying heat to the substrate to anneal the repassivation material.

4. The method of claim 1, wherein the curing is performed without using a mask.

5. The method of claim 1, wherein the depositing is performed without using a mask.

6. The method of claim 1, wherein the specified locations include portions of the substrate surface containing exposed conductive traces or exposed conductive vias.

7. The method of claim 6, wherein the depositing step uses a same design layout database to target the specified locations using the inkjet printer as was used to fabricate the exposed conductive traces or exposed conductive vias.

8. The method of claim 1, wherein the specified portions include portions of the substrate surface containing exposed surfaces of conductive pillars.

9. The method of claim 8, further comprising electrically coupling the substrate to a printed circuit board (PCB) using solder balls, respective ones of the solder balls contacting corresponding ones of the exposed surfaces of the conductive pillars.

10. The method of claim 1, wherein the specified portions include portions of the substrate surface between electrically disjoint integrated circuits in the substrate.

11. The method of claim 10, further comprising cutting the substrate along at least some of the specified portions to provide multiple dies.

12. The method of claim 1, wherein the repassivation material solidifies when the curing is performed, and protects structure covered by the repassivation material against oxidation.

13. The method of claim 1, wherein the repassivation material includes one or more of: an epoxy, a bismaleimide, a silicone, and a polyimide.

14-20. (canceled)

21. A method of making an integrated circuit, the method comprising:
fabricating multiple electrically disjoint integrated circuits on a substrate, so that a portion of at least one of the integrated circuits is located on a surface of the substrate;
depositing an ink comprising particles of a repassivation material onto specified locations on the substrate surface using an inkjet printer, so that specified regions of the portion of the integrated circuit on the substrate surface are not covered by the ink, the specified locations including a first part of the portion of the integrated circuit located on the substrate surface;
curing the repassivation material; and
singulating the substrate between the multiple electrically disjoint integrated circuits.

22. The method of claim 21, wherein the first part of the portion of the integrated circuit has an elevated risk of performance loss caused by environmental exposure to reactive materials, including moisture, without a coating of the repassivation.

23. The method of claim 21, wherein the specified portions of the substrate surface not covered by the ink include at least a second part of the portion of the integrated circuit, the second part of the portion of the integrated circuit does not have an elevated risk of performance loss caused by environmental exposure to reactive materials, including moisture, without a coating of the repassivation.

24. The method of claim 21, wherein the depositing step is performed without using a mask.

25. The method of claim 21, wherein the curing step includes performing UV-pinning.

26. A method of making an integrated circuit, the method comprising:
fabricating multiple electrically disjoint integrated circuits on a substrate, so that a portion of at least one of the integrated circuits is located on a surface of the substrate;
depositing particles of a repassivation material onto specified locations on the substrate surface, so that specified regions of the portion of the integrated circuit on the substrate surface are not covered by the repassivation material, the specified locations including a first part of the portion of the integrated circuit located on the substrate surface; and
curing the repassivation material.

27. The method of claim 26, wherein the first part of the portion of the integrated circuit has an elevated risk of performance loss caused by environmental exposure to reactive materials, including moisture, without a coating of the repassivation.

28. The method of claim 27, wherein the specified portions of the substrate surface not covered by the passivation material include at least a second part of the portion of the integrated circuit, the second part of the portion of the integrated circuit does not have an elevated risk of performance loss caused by environmental exposure to reactive materials, including moisture, without a coating of the repassivation.

29. The method of claim 27, wherein the depositing step is performed without using a mask.

30. The method of claim 27, wherein the curing step includes performing UV-pinning.

31. An apparatus, comprising:
multiple electrically disjoint integrated circuits on a substrate, a portion of at least one of the integrated circuits is located on a surface of the substrate; and
cured particles of an ink based repassivation material on specified locations on the surface of the substrate but not on other locations on the surface of the substrate, the specified locations including a first part of the portion of the integrated circuit located on the substrate surface.

32. The apparatus of claim 31, wherein the first part of the portion of the integrated circuit is vulnerable to reactive environmental factors.

33. The apparatus of claim 31, wherein the locations of the substrate surface not covered by the passivation material include at least a second part of the portion of the integrated circuit, the second part of the portion of the integrated circuit not vulnerable to reactive environmental factors or configured to electrically couple the integrated circuit to a circuit on a printed circuit board.

34. The apparatus of claim 31, wherein the passivation material was deposited without using a mask.

35. The apparatus of claim 31, wherein the passivation material was cured via UV-pinning.
